(19) United States
(12) Patent Application Publication
(10) Pub. No.: US 2002/0192984 A1
(43) Pub. Date: Dec. 19, 2002

(54) Method for manufacturing semiconductor device, method for processing substrate, and substrate processing apparatus

(75) Inventors: Shin Hiyama, Nakano-ku (JP); Masato Terasaki, Nakano-ku (JP); Yuji Takebayashi, Nakano-ku (JP); Osamu Kasahara, Nakano-ku (JP)

Correspondence Address: OLIFF & BERRIDGE, PLC, P.O. BOX 19928, ALEXANDRIA, VA, 22320, US

(73) Assignee: HITACHI KOKUSAI ELECTRIC INC., Nakano-ku (JP)

(21) Appl. No.: 10/126,667

(22) Filed: Apr. 22, 2002

(30) Foreign Application Priority Data
Jun. 4, 2001 (JP) 2001-167723

(51) Int. Cl. H01L 21/31

(52) U.S. Cl. 438/792; 118/722

(57) ABSTRACT

A processing chamber of a plasma CVD device comprises a lower electrode for placing a semiconductor substrate thereon and an upper electrode provided at a position facing the lower electrode and provided with a concave portion on a surface thereof facing a surface of the lower electrode on which the substrate is placed. In deposition process using such a processing chamber, a contaminant removal sequence is provided between a deposition processing step and an exhausting step. During the deposition process, reactive gases SiH₄ and NH₃ for forming a Si₃N₄ film are supplied together with an inert gas N₂ into the processing chamber. High-frequency electric power is applied between the electrodes to discharge the reactive gases so as to form the Si₃N₄ film on the semiconductor substrate. During the contaminant removal sequence after the deposition processing, processing conditions are changed while the high-frequency discharge is maintained to eliminate a hollow discharge so that contaminants captured in the concave portion of the electrode are removed from the processing chamber. The processing conditions are changed by stopping the supply of the SiH₄ and NH₃ gases, continuing the supply of the N₂ gas, and decreasing the high-frequency electric power and a processing pressure. After the processing conditions are changed, the inside of the processing chamber is exhausted to produce a high vacuum.

### BACKGROUND OF THE INVENTION

1. Field of the Invention

The present invention relates to a method for manufacturing a semiconductor device, a method for processing a substrate, and a substrate processing apparatus and particularly, the present invention is preferable to be applied to a plasma CVD device.

2. Description of the Related Art

One of the steps for manufacturing a semiconductor is a plasma CVD (Chemical Vapor Deposition) deposition step in which a predetermined deposition is performed on a substrate. Specifically, the substrate is placed in an vacuum processing chamber, high-frequency electric power is applied while a deposition gas is supplied between a pair of electrodes provided in the processing chamber to cause a high-frequency discharge so that plasma is generated between the pair of electrodes. The plasma decomposes deposition gas molecules to form a thin film on a surface of the substrate.

If surfaces of the aforesaid pair of electrodes facing each other are plane, plasma density becomes comparatively low, which is inappropriate for a process requiring high-density plasma, Accordingly, it has been proposed that one or a plurality of non-plane portions such as holes, recesses, or slots (hereinafter referred to as concave portions) are formed to generate a hollow discharge so as to improve gas-decomposing efficiency and a deposition rate compared with those by conventional plane electrodes (as in Japanese Patent Laid-open No. Hei 9-22798, for example).

Here, the hollow discharge means a discharge in a hollow, that is, a concave portion, and an electron capturing phenomenon is produced in the concave portion to form high-density plasma. In the high-frequency discharge, a “cathode” as is meant in a DC discharge does not exist. However, it is possible, also in the high-frequency discharge, to produce the electron capturing phenomenon similar to a hollow cathode discharge by forming a concave portion on a surface of an electrode and, by using this, form high-density plasma The above-described hollow discharge utilizes a phenomenon in which the plasma is drawn into the concave portion. In this case, electrons are electrostatically captured in the concave portion by surrounding potential barriers and cumulatively ionized to grow and, as a result, high-density plasma is obtained in the concave portion.

However, in the plasma, the gas molecules collide with each other and impalpable particles composed of contaminants grown in a vapor phase or reaction products (hereinafter simply referred to as contaminants) are formed. The contaminants are often charged negatively and captured by a potential formed in the concave portion during the discharge. Therefore, in the concave portion during the discharge, the contaminants collide with each other and thereby the particle size of the contaminants greatly grows as well as a large amount of the contaminants are built up in the concave portion. When the discharge is finished, the capturing potential is lost simultaneously and the contaminants fall on and adhere to the substrate on which the film is formed, which causes a product defect.

This is not limited to the deposition and also occurs in substrate processing including diffusion and etching.

### SUMMARY OF THE INVENTION

It is an object of the present invention to provide a method for manufacturing a semiconductor device, a method for processing a substrate, and a substrate processing apparatus capable of greatly reducing the number of contaminants on a processed substrate by solving the above-described problem in the conventional art.

The invention described in claim 1 is a method for manufacturing a semiconductor device in which a semiconductor substrate is processed using a processing chamber having therein a first electrode on which the semiconductor substrate is placed and a second electrode provided at a position facing the first electrode and provided with a concave portion on a surface thereof facing a surface of the first electrode on which the substrate is placed, comprising the steps of: processing the semiconductor substrate by applying high-frequency electric power between the electrodes to discharge a reactive gas supplied into the processing chamber so that plasma is formed; and changing processing conditions for processing the semiconductor substrate while maintaining the discharge and exhaust of the inside of the processing chamber after the semiconductor substrate is processed. The processing of the semiconductor substrate includes diffusion, etching, and so on in addition to the deposition. Further, the exhaust of the inside of the processing chamber includes removal of contaminants captured in the concave portion of the second electrode from the processing chamber.

When the concave portion is provided in the second electrode, the concave portion works as a space for discharge and discharge efficiency is improved so that high-density plasma is obtained. At the same time, the contaminants are captured in the concave portion. If the processing conditions for processing the semiconductor substrate are changed after the semiconductor substrate is processed, the contaminants captured in the concave portion are released from the concave portion. At this time, since the discharge is maintained to keep the formed plasma, the contaminants released from the concave portion are removed from the processing chamber without falling on and adhering to the substrate. Therefore, the number of contaminants on the processed semiconductor substrate greatly decreases.

The invention described in claim 2 is the method for manufacturing the semiconductor device according to claim 1, in which the processing conditions are changed to eliminate a hollow discharge in the concave portion of the second electrode. If the hollow discharge is eliminated while the discharge is maintained after the processing, the contaminants are released from being captured in the concave portion of the second electrode and removed from the processing chamber more easily, which greatly reduces the number of the contaminants on the semiconductor substrate.

The invention described in claim 3 is the method for manufacturing the semiconductor device according to claim 2, in which the processing conditions include a processing pressure and, in the step of changing the processing conditions, the processing conditions are changed so that the processing pressure is lowered to a value lower than that before the step of changing the processing conditions. The processing pressure is a processing condition which has the closest relation with the generation of the hollow discharge and the hollow discharge can be easily eliminated if the processing pressure is lowered. In addition, if a flow rate of a gas supplied into the processing chamber is the same value, the contaminants can be blown out more easily at a lower processing pressure, and thus the contaminants can be easily removed.

The invention described in claim 4 is the method for manufacturing the semiconductor device according to claim 1, in which the processing conditions include a kind of gas, a gas flow rate, a processing pressure, high-frequency electric power, a frequency of electric power, and an electrode distance and, in the step of changing the processing conditions, one or a plurality of the processing conditions are changed. The processing conditions related to the generation of the hollow discharge are the kind of gas, the gas flow rate, the processing pressure, the high-frequency electric power, the frequency of electric power, and the electrode distance, and the hollow discharge can be eliminated by changing one or a plurality of these processing conditions.

The invention described in claim 5 is a method for manufacturing a semiconductor device in which a film is formed on a semiconductor substrate by supplying SiH₄ and NH₃ as reactive gases into a processing chamber having therein a first electrode on which the semiconductor substrate is placed and a second electrode provided at a position facing the first electrode and provided with a concave portion on a surface thereof facing a surface of the first electrode on which the substrate is placed, comprising the steps of: forming a Si₃N₄ film on the semiconductor substrate by applying high-frequency electric power between the electrodes to discharge the reactive gases supplied into the processing chamber so that plasma is formed; and switching the reactive gases to a non-reactive gas which does not independently affect deposition while maintaining the discharge after the Si₃N₄ film is formed to exhaust the inside of the processing chamber. The step of exhausting the inside of the processing chamber includes the removal of the contaminants captured in the concave portion of the second electrode from the processing chamber.

If the kind of gas is switched from the relative gas to the non-reactive gas after the Si₃N₄ film is formed, the contaminants captured in the concave portion of the second electrode are released from the concave portion. At this time, since the discharge is maintained to keep the formed plasma, the contaminants released from the concave portion are exhausted from the processing chamber together with the non-reactive gas without falling on and adhering to the substrate. Therefore, the number of the contaminants on the processed substrate also greatly decreases. The gas for releasing and removing the contaminants from the concave portion is the non-reactive gas so as not to form a film on the substrate even if the discharge is maintained. As the non-reactive gas, nitrogen only, or combination of NH₃ and N₂ can be used in place of the SiH₄ and NH₃.

The invention described in claim 6 is a method for processing a substrate in which a substrate is processed using a processing chamber having therein a first electrode on which the substrate is placed and a second electrode provided at a position facing the first electrode and provided with a concave portion on a surface thereof facing a surface of the first electrode on which the substrate is placed, comprising the steps of: processing the substrate by applying high-frequency electric power between the electrodes to discharge a reactive gas so that plasma is formed; and changing a processing condition for processing the substrate while maintaining the discharge and exhaust of the inside of the processing chamber after the substrate is processed. The substrate is not limited to a semiconductor substrate and includes a glass substrate and the like. The exhaust of the inside of the processing chamber also includes the removal of the contaminants captured in the concave portion of the second electrode from the processing chamber.

When the processing condition for processing the semiconductor substrate is changed after the substrate is processed, the contaminants captured in the concave portion of the second electrode are released from the concave portion. At this time, since the discharge is maintained to keep the formed plasma, the contaminants released from the concave portion are exhausted from the processing chamber without falling on and adhering to the substrate. Therefore, the number of the contaminants on the processed substrate also greatly decreases.

The invention described in claim 7 is a substrate processing apparatus, comprising: a processing chamber for processing the substrate; a first electrode for placing the substrate thereon in the processing chamber; a second electrode provided at a position facing the first electrode and provided with a concave portion on a surface thereof facing a surface of the first electrode on which the substrate is placed; and a control apparatus that performs control, after the substrate is processed by applying high-frequency electric power between the electrodes to discharge a reactive gas, so as to change a processing condition for processing the substrate while maintaining the discharge and exhaust of the inside of the processing chamber. The control apparatus that changes the processing condition while the discharge and the exhaust of the inside of the processing chamber is maintained is provided, which reduces falling and adhesion of the contaminants onto the substrate. Incidentally, the step of exhausting the inside of the processing chamber includes the removal of the contaminants captured in the concave portion of the second electrode from the processing chamber.

### BRIEF DESCRIPTION OF THE DRAWINGS

FIG. 1 is a timing chart explaining an embodiment;

FIG. 2 is a timing chart explaining another embodiment;

FIG. 3 is a vertical cross-sectional view of a processing chamber of a plasma CVD device explaining the embodiments;

FIG. 4 is a block diagram of a control system of the plasma CVD device explaining the embodiments;

FIG. 5 is a conceptual view in the processing chamber during deposition process explaining the embodiments;

FIG. 6 is a conceptual view in the processing chamber during a contaminant removal sequence processing explaining the embodiments;

FIG. 7 is a conceptual view in the processing chamber when desposition process is completed explaining the embodiments; and

FIG. 8 is a conceptual view in the processing chamber when deposition process is completed explaining a comparative example to the embodiments.

### DETAILED DESCRIPTION OF THE PREFERRED EMBODIMENTS

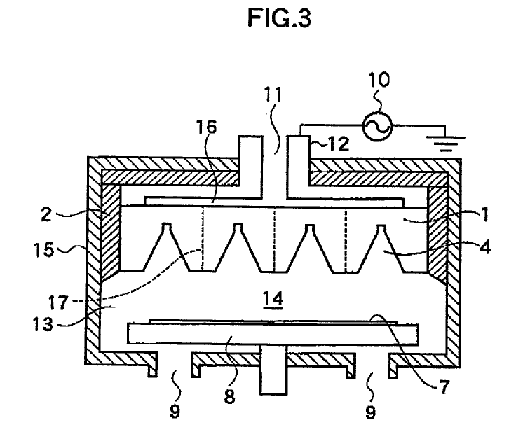

Embodiments of a method for manufacturing a semiconductor device, a method for processing a substrate, and a substrate processing apparatus according to the present invention will be described below. FIG. 3 is a schematic explanatory view of a plasma CVD device of the embodiments. This device performs a plasma CVD (Chemical Vapor Deposition) deposition step, which is one of the steps for manufacturing a semiconductor, in which predetermined deposition is performed on a substrate. Incidentally, the semiconductor device includes an IC fabricated in a manner in which predetermined processing is performed on a semiconductor substrate made of silicon or the like, a liquid crystal display device fabricated in a manner in which predetermined processing is performed on a glass substrate, and the like.

A processing chamber 13 for processing a semiconductor substrate 7 made of silicon or the like is formed in a vacuum chamber 15. From a ceiling portion to upper inner walls of the processing chamber 13, a gas inlet pipe 12 and an upper electrode 1 connected thereto as a second electrode are provided, both of which are insulated from the vacuum chamber 15 by an insulating material 2. The gas inlet pipe 12 is connected with the upper electrode 1 also electrically to compose an extraction terminal of the upper electrode 1. At a connecting part of the upper electrode 1 and the gas inlet pipe 12, a gap 16 for diffusing a gas introduced from a gas flow channel 11 of the gas inlet pipe 12 on the upper electrode 1 is formed. Many gas dispersing holes 17 are formed in the upper electrode 1. A reactive gas introduced from the gas inlet pipe 12 is supplied into a plasma processing space 14, which will be described later, in a showering way from the gas dispersing holes 17 through the gap 16. In a lower portion of the processing chamber 13, a lower electrode 8 as a first electrode is provided to pair up with the upper electrode 1, and a not-shown heater is embedded in the lower electrode 8 to heat the substrate 7 placed on the lower electrode 8.

Concave portions 4 are provided on a surface of the upper electrode 1 facing a surface of the aforesaid lower electrode 8 on which the substrate is placed. Side faces of the concave portions 4 are formed in a tapered shape or a step shape so that the cross-sectional area becomes smaller as the depth gets deeper. Electrons are captured in the concave portions 4 and thereby, discharge efficiency is improved, which leads to improvement in gas-decomposition efficiency and a deposition rate.

The plasma processing space 14 is formed in a space surrounded by the upper electrode 1, the inner walls of the processing chamber 13, and the lower electrode 8. While a deposition gas as a reactive gas is supplied from the gas inlet pipe 12 through the gas dispersing holes 17 into the plasma processing space 14, high-frequency electric power is applied to the upper electrode 1 from a high-frequency power source 10 through the gas inlet pipe 12. The lower electrode 8 is grounded. By this application, a high-frequency discharge is generated between the electrodes 1 and 8, plasma is formed in the plasma processing space 14, gas molecules in the deposition gas are decomposed, so that a required thin film is produced on the substrate 7. At a bottom of the vacuum chamber 15, exhaust pipes 9 are connected, and the gas introduced into the processing chamber 13 is exhausted from the exhaust pipes 9.

In the case of producing the required thin film on the substrate 7, SiH₄, Si₂H₆, SiH₂Cl₂, NH₃, PH₃, or the like is introduced as a deposition gas from the reactive gas inlet pipe 12.

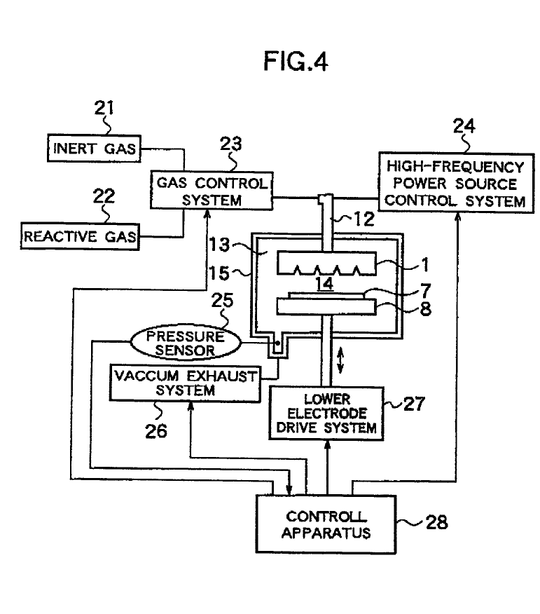

FIG. 4 is a block diagram showing a control system of the above-described plasma CVD device. A gas control system 23, a high-frequency power source control system 24, a vacuum exhaust system 26, a lower electrode drive system 27, and a pressure sensor 25 are deployed around the processing chamber 13. They are integrally controlled by a control apparatus 28 composed of a CPU and so on.

The gas control system 23 supplies reactive gases 22 such as an SiH₄ gas and an NH₃ gas for deposition and an inert gas 21 such as an N₂ gas for securing uniformity into the processing chamber 13 and controls flow rates of the gases. If gases supplied into the processing chamber 13 are only the SiH₄ gas and the NH₃ gas, plasma does not spread to a periphery of the electrodes, which deteriorates plasma distribution. For this reason, the N₂ gas is also supplied to uniformly carry molecules and radicals of the SiH₄ gas and the NH₃ gas to the periphery so as to adjust a film thickness and in-plane distribution.

The exhaust system 26 adjusts power of a vacuum pump and so on based on information on a pressure in the processing chamber 13 detected by the pressure sensor 25 to control the pressure in the processing chamber 13. The high-frequency power source control system 24 controls high-frequency application electric power or a high frequency to be applied to the upper electrode 1. The lower electrode drive system 27 raises and lowers the lower electrode 8 so that an electrode distance with respect to the upper electrode 1 is controlled.

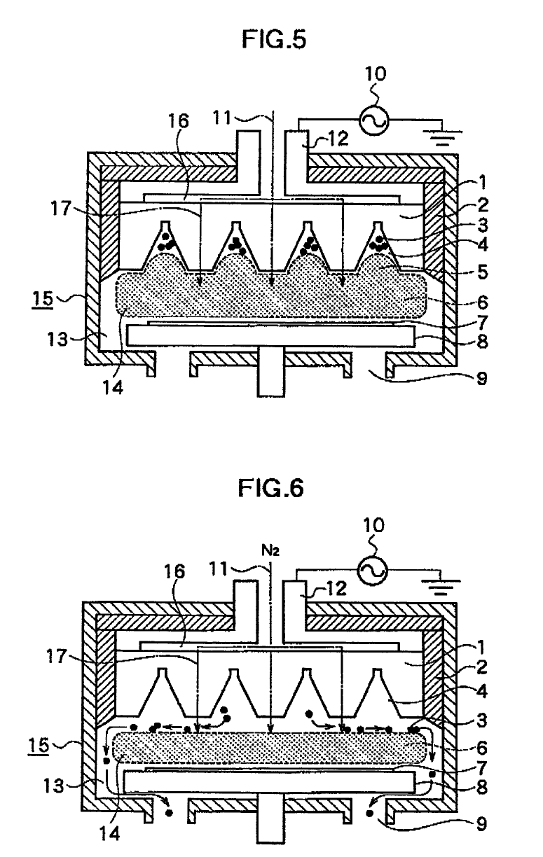

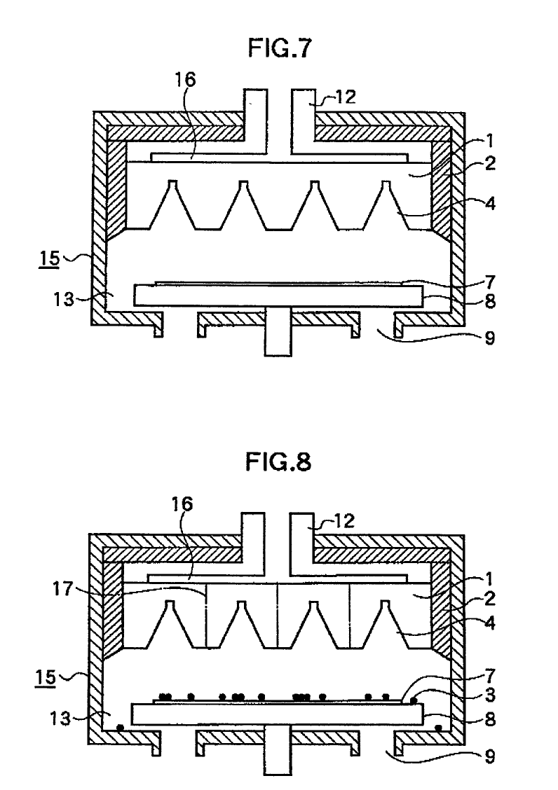

Operation of the above-described configuration will be next explained with reference to FIG. 5 to FIG. 7. FIG. 5 is a conceptual view during the deposition process, FIG. 6 is a conceptual view of a contaminant removal sequence performed after the deposition, and FIG. 7 is a conceptual view during vacuum exhausting performed after the contaminant removal sequence.

In the deposition, reactive gases are supplied into the processing chamber 13 through the gas flow channel 11, High-frequency electric power is applied to the upper electrode 1 from the high-frequency power source 10, the reactive gases are discharged at a high frequency between the electrodes 1 and 8 to form plasma 6 in the plasma processing space 14, and a thin film is formed on the substrate 7. At this time, gas molecules collide with each other in the plasma 6 to form contaminants 3. The contaminants 3 are often charged negatively, as described above, and during the discharge, portions 5 having a high effect for capturing electrons in the plasma 6 are formed in the concave portions 4 of the upper electrode 1 to which the high-frequency electric power is applied (FIG. 5). Thus, in the concave portions 4 during the discharge, the contaminants 3 collide with each other and thereby, their particle size greatly grows as well as a large amount of the contaminants 3 are built up.

In the contaminant removal sequence after the deposion is completed, processing in which one or a plurality of processing conditions (a kind of gas, a gas flow rate, a gas pressure, high-frequency application electric power, a frequency of electric power, and an electrode distance) are changed (hereinafter referred to as contaminant removal processing) is performed while the discharge is maintained. As a result, a hollow discharge in the concave portions 4 can be eliminated so that the contaminants 3 in the concave portions 4 become able to move freely to some extent. Since the contaminants 3 are captured at an edge of the plasma 6 on the plane parts of the electrodes (a plasma sheath part), the contaminants 3 move along the edge of the plasma 6 as shown by arrows with flow of the gases, without falling on and adhering to the substrate 7, and are exhausted from the processing chamber 13 through the exhaust pipes 9 (FIG. 6). The discharge is maintained for several seconds to exhaust the contaminants 3, and the discharge is stopped.

In the exhausting after the contaminant removal sequence, the supply of the gases and the application of the high-frequency electric power are stopped to complete the discharge, and the inside of the processing chamber 13 is exhausted through the exhaust pipes 9 to produce a high vacuum in the processing chamber 13. Accordingly, the contaminants 3 can be effectively prevented from falling on and adhering to the substrate 7 after the processing (FIG. 7).

If the above-described contaminant removal sequence is not performed after the substrate is processed, as shown in FIG. 8, the plasma disappears and the capturing potential is lost simultaneously when the discharge is finished, and thereby the contaminants 3 in the concave portions 4 fall on and adhere to the substrate 7, which causes a product defect.

A timing chart when the deposition process corresponding to the above-explained FIG. 5 to FIG. 7 is applied to a case of forming a nitride silicon film (Si₃N₄ film) is shown in FIG. 1. Here, in the contaminant removal sequence after the Si₃N₄ film is formed under predetermined conditions, the supply of deposition gases is stopped while the discharge is maintained so as to reduce high-frequency electric power (RF electric power) and a pressure.

Firstly, in a step of the deposition processing, an SiH₄ gas in a flow rate of 300 sccm to 600 sccm and an NH₃ gas in a flow rate of 1000 sccm to 3000 sccm are supplied from the gas control system 23. A flow rate of an N₂ gas to be supplied is set at 3000 sccm to 10000 sccm. RP electric power from the high-frequency power source 10 is used in a range of 3000 W to 5000 W, preferably in a range of 3000 W to 4500 W. It is recommended to set a processing pressure in the processing chamber 13 at 240 Pa to 300 Pa and 266 Pa (2.0 Torr) to 300 Pa immediately before the deposition is completed. The deposition is performed under these conditions. Deposition processing time is 1 to 2 minutes.

In a step of contaminant processing after the deposition processing, processing conditions are changed as follows while the high-frequency discharge is maintained to keep the formed plasma.

The pressure in the processing chamber 13 is lowered to approximately 133 Pa (1 Torr) by controlling the vacuum exhaust system 26 in response to a command from the control apparatus 28 based on information obtained by the pressure sensor 25. It is not necessarily obvious at what level of the processing pressure a hollow discharge in the concave portions 4 provided in the upper electrode 1 is generated. However, a boundary when a discharge mode changes is in a range of 186.2 Pa to 219.45 Pa (1.4 Torr to 1.65 Torr) although there are some degree of differences depending on hardware such as capacity or a form of the processing chamber 13 and performance of the vacuum pump, and it is assumed that the hollow discharge is effectively generated on a higher pressure side than the boundary. Accordingly, since the boundary needs to be avoided in order to allow contaminants in the concave portions 4 of the upper electrode 1 to move freely to some extent by eliminating the hollow discharge in the concave portions, the processing pressure is preferably lowered to at least 159.6 Pa (1.2 Torr) or lower, more preferably, to approximately 133 Pa (1 Torr).

At the same time, the gas control system 23 is controlled to stop the supply of the SiHi₄ gas and the NH₃ gas which are involved in forming the film so as to complete the deposition processing. However, the supply of the N₂ gas, which is an inert gas, is continued. A flow rate of the N₂ gas can be set at the same value as in the deposition processing, that is, 3000 sccm to 10000 sccm, and preferably at 8000 sccm. The supply of the inert gas is continued in order: 1. to maintain the high-frequency discharge; 2. not to affect the deposition; and 3. to remove the contaminants from the processing chamber with flow of the gas.

Further, the high-frequency power source control system 24 is controlled to decrease the RF electric power to 3000 W or lower, preferably to 1000 W. The RF electric power is not decreased to zero in order to maintain the plasma discharge so that the negatively-charged contaminants are prevented from adhering to the substrate 7. Moreover, the discharge is maintained at RF electric power lower than that when the deposition is performed in order to prevent a surface of the thin film formed on the substrate 7 from being damaged by the plasma. In addition, since the plasma discharge becomes N₂ discharge, the RF electric power needs to be decreased to a power which does not cause abnormal discharge.

Time for the contaminant removal sequence, that is, time for eliminating the hollow discharge, is preferably at least 3 seconds or longer in order to enhance a blowing-out effect by the gas. In other words, the time can be shortened to 3 seconds.

In an exhausting step after the contaminant removal sequence, the supply of the N₂ gas is stopped and the supply of the RF electric power is also stopped. Then, an atmosphere in the processing chamber 13 is exhausted from the exhaust pipes 9 to produce a high vacuum in the processing chamber 13, and thereby the contaminants in the processing chamber 13 are eliminated substantially perfectly and the deposition process is completed.

By adopting a deposition process based on the above-described timing chart, a Si₃N₄ film including an extremely few contaminants can be formed on a silicon substrate.

In the aforesaid embodiment in FIG. 1, in order to complete the deposition while maintaining the discharge after the deposition, the supply of both gases of the SiH₄ gas and the NH₃ gas is stopped and the supply of the N₂ gas is continued as it is. However, it is also suitable that, after the deposition, the supply of only one of the reactive gases is stopped and the supply of the other gas is continued while the discharge is maintained. The reason is that one of the reactive gases and the N₂ gas are the gases each of which does not independently affect the deposition.

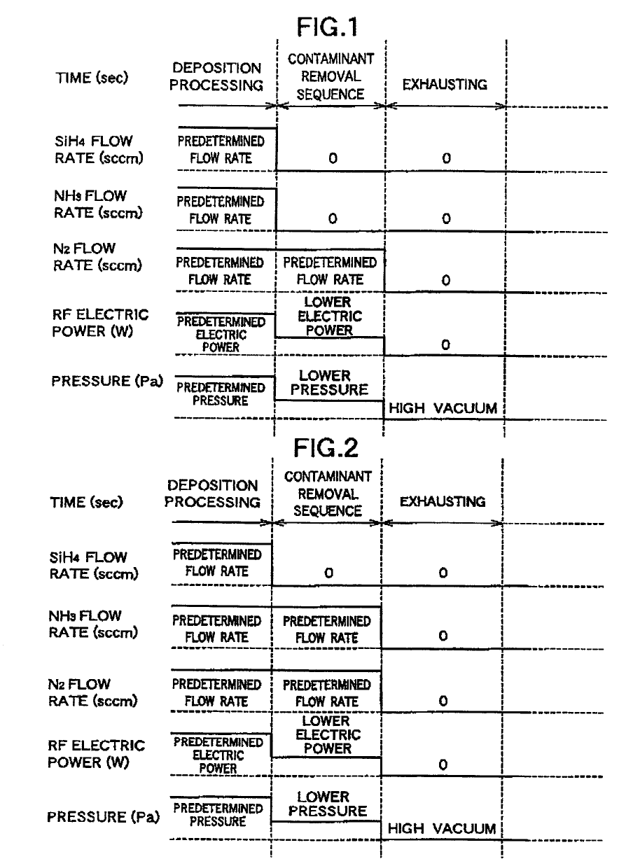

A timing chart of deposition processing, a contaminant removal sequence, and exhausting of such an embodiment is shown in FIG. 2. A different point from the embodiment in FIG. 1 is that, in the contaminant removal sequence after the deposition processing, the supply of only the SiH₄ gas is stopped and the supply of the NH₃ gas and the N₂ gas is continued as it is while the discharge after the deposition is maintained. As a result, a flow rate of gases supplied during the contaminant removal sequence can be set to be higher than that in the embodiment in FIG. 1, which enhances the blowing-out effect by the gases. From viewpoints of controllability in changing the processing conditions and the effect of blowing off the contaminants by the gases, the embodiment in FIG. 2 is assumed to be more preferable.

Incidentally, in the above-described embodiments, as conditions when the processing conditions are changed while the discharge is maintained for removing the contaminants, a kind of gas, the magnitude of RF electric power, and a processing pressure are explained, but there are also distance between both electrodes, a gas flow rate, and an RF frequency.

As for both the electrodes 1 and 8, the lower electrode drive system 27 is moved in response to a command from the control apparatus 28 to change the distance therebetween from a large value to a small value. As a result, the blowing-out effect by the gases is enhanced and an effect of eliminating the contaminants can be improved. For example, the distance of approximately 20 mm to 30 mm during the deposition processing is recommended to be narrowed to approximately 10 mm to 15 mm.

Further, as for the gas flow rate, the gas control system 23 is controlled to change the flow rate from a small value to a large value. Flow of a large amount of gas pushes the contaminants out of the processing chamber 13, which enhances the blowing-out effect.

Furthermore, as for the RF frequency, the RF frequency is changed from a high level to a low level because the contaminants captured in the concave portions are more easily eliminated at the lower level.

Incidentally, in the above-described embodiments, in changing the processing conditions while the discharge is maintained, as the gases to be supplied after the supply of the reactive gas which is a material of the contaminants is stopped, N₂ is explained as an example of an inert gas and NH₃ gas is explained as an example of a gas which does not independently affect the deposition. However, as the inert gas, Ar, He, Ne, Xe, or the like can be used other than the N₂. On the other hand, as the gas which does not independently affect the deposition, PH₃, H₂, or the like, or a mixed gas of these gases can be used other than the NH₃. The reason is that the purpose is only to prevent a film of a different film characteristic from depositing on a surface of a formed thin film. Combinations of a kind of film including the above-explained Si₃N₄ film and a gas to be supplied after the deposition are as follows:

| kind of film (gas) | gas to be supplied after deposition |
|---|---|
| 1. SiN(SiN₄ + NH₃ + N₂) | → N₂ or (NH₃ + N₂) |
| 2. a-Si(SiH₄ + H₂) | → H₂ |
| 3. n⁺a-Si(SiH₄ + H₂ + PH₃) | → H₂ or (H₂ + PH₃) |

A process to which the present invention is particularly preferably applied is a case in which deposition is performed at a high speed or a thickness of a film to be formed is large, as in a case of forming a Si₃N₄ film (at a deposition rate of approximately 200 n/min in a film thickness of 500 nm to 700 nm). In this case, since a large amount of gas is supplied, contaminants are generated especially easily, and therefore, the present invention is particularly effective in such a process.

According to the present invention, processing conditions are changed while a discharge is maintained after a substrate is processed, which makes it possible to greatly reduce the number of contaminants on the processed substrate, resulting in elimination of a product defect.

What is claimed is:

1. A method for manufacturing a semiconductor device in which a semiconductor substrate is processed using a processing chamber having therein a first electrode on which the semiconductor substrate is placed and a second electrode provided at a position facing the first electrode and provided with a concave portion on a surface thereof facing a surface of the first electrode on which the substrate is placed, comprising the steps of:
processing the semiconductor substrate by applying high-frequency electric power between the electrodes to discharge a reactive gas supplied into the processing chamber so that plasma is formed; and
changing processing conditions for processing the semiconductor substrate while maintaining the discharge and exhaust of an inside of the processing chamber after the semiconductor substrate is processed.

2. The method for manufacturing the semiconductor device according to claim 1,
wherein the processing conditions are changed to eliminate a hollow discharge in the concave portion of the second electrode.

3. The method for manufacturing the semiconductor device according to claim 2,
wherein the processing conditions include a processing pressure and, in said step of changing the processing conditions, the processing conditions are changed so that the processing pressure is lowered to a value lower than that before said step of changing the processing conditions.

4. The method for manufacturing the semiconductor device according to claim 1,
wherein the processing conditions include a kind of gas, a gas flow rate, a processing pressure, high-frequency electric power, a frequency of electric power, and an electrode distance and, in said step of changing the processing conditions, one or a plurality of the processing conditions are changed.

5. A method for manufacturing a semiconductor device in which a Si₃N₄ film is formed on a semiconductor substrate by supplying SiH₄ and NH₃ as reactive gases into a processing chamber having therein a first electrode on which the semiconductor substrate is placed and a second electrode provided at a position facing the first electrode and provided with a concave portion on a surface thereof facing a surface of the first electrode on which the substrate is placed, comprising the steps of:
forming the Si₃N₄ film on the semiconductor substrate by applying high-frequency electric power between the electrodes to discharge the reactive gases supplied into the processing chamber so that plasma is formed; and
switching the reactive gases to a non-reactive gas which does not independently affect deposition while maintaining the discharge after the Si₃N₄ film is formed to exhaust an inside of the processing chamber.

6. A method for processing a substrate in which a substrate is processed using a processing chamber having therein a first electrode on which the substrate is placed and a second electrode provided at a position facing the first electrode and provided with a concave portion on a surface thereof facing a surface of the first electrode on which the substrate is placed, comprising the steps of:
processing the substrate by applying high-frequency electric power between the electrodes to discharge a reactive gas supplied into the processing chamber so that plasma is formed; and
changing a processing condition for processing the substrate while maintaining the discharge and exhaust of an inside of the processing chamber after the substrate is processed.

7. A substrate processing apparatus, comprising:
a processing chamber for processing the substrate;
a first electrode for placing the substrate thereon in said processing chamber;
a second electrode provided at a position facing said first electrode and provided with a concave portion on a surface thereof facing a surface of said first electrode on which the substrate is placed; and
a control apparatus that performs control, after the substrate is processed by applying high-frequency electric power between said electrodes to discharge a reactive gas so that plasma is formed, so as to change a processing condition for processing the substrate while maintaining the discharge and exhaust of so that an inside of said processing chamber is exhausted.
